(19) United States
(12) Patent Application Publication
(10) Pub. No.: US 2022/0328860 A1
(43) Pub. Date: Oct. 13, 2022

(54) CERAMIC LITHIUM BATTERY WITH PIEZOELECTRIC COMPENSATION LAYERS

(71) Applicant: Sakuu Corporation, San Jose, CA (US)

(72) Inventor: Arwed NIESTROJ, Campbell, CA (US)

(73) Assignee: Sakuu Corporation, San Jose, CA (US)

(21) Appl. No.: 17/226,487

(22) Filed: Apr. 9, 2021

(51) Int. Cl. H01M 10/04; H01M 10/052; H01M 4/38; B33Y 80/00; H01M 10/0562; H01M 10/0585; H01M 50/244; H01M 10/48; H01L 41/09

(52) U.S. Cl. CPC H01M 10/0468; H01M 10/052; H01M 4/382; B33Y 80/00; H01M 10/0562; H01M 10/0585; H01M 50/244; H01M 10/48; H01L 41/0986; H01M 2004/027

(57) ABSTRACT

A solid-state battery cell includes a cathode region, an anode region, a separator interconnecting the cathode region and the anode region, a cathode current collector on a surface of the cathode region, an anode current collector on a surface of the anode region, a first piezoelectric layer on a surface of the cathode current collector, and a second piezoelectric layer on a surface of the anode current collector. A method of operating a solid-state battery cell includes detecting a material change in the anode or the cathode, applying a voltage to the first piezoelectric material layer or the second piezoelectric material layer, and generating a pressure against the cathode current collector or the anode current collector by the first piezoelectric material layer or the second piezoelectric material layer, the pressure being generated as a result of the applied voltage.

### TECHNICAL FIELD

This application relates to solid-state batteries, and in particular to ceramic solid-state batteries including piezoelectric layers configured to compensate for material changes during operation thereof.

### BACKGROUND

Batteries with lithium metal anodes provide a high energy density among currently commercially available batteries. While the reduction/oxidation reactions that liberate the energy from the lithium metal chemistry are reversible, rechargeable batteries with lithium metal anodes are not largely commercially available. Such rechargeable batteries may not be largely commercially available because of the potential of fire and explosion that may be caused by the growth of lithium dendrites during the recharge cycle of a solid-state battery. The lithium dendrites that may grow in the anode during the recharge cycle may extend through the solid-state electrolyte, and even through the cathode, and create a short circuit directly between the anode and cathode. Several strategies for preventing shorting dendrites have been advanced with varying degrees of success, but none have yet reached the level of safety required for commercial acceptance. Among some approaches for reducing the fire and explosion risk in advanced LIBs (Lithium Ion Batteries) with lithium metal anodes is the use of solid-state, ceramic electrolyte as the separator between anode and cathode.

During operation of a solid-state battery, both the anode and the cathode may undergo material changes as well as changes in mechanical forces between the various layers of the solid-state battery. These changes may be caused by, e.g., material transport such as Lithium ions, volume changes due to material transport. As a result, the interface between the anode or cathode and the current collector may deteriorate, which may lead to a deterioration in the amount of power being generated or in the recharging ability of the solid-state battery. Typically, to improve the electrical interface between the various layers of a solid-state battery, cell manufacturers apply some amount of mechanical pressure to the battery layers using, e.g., a spring inside a coin cell. For example, higher pressures applied to the various layers typically result in better interfaces between the layers, and thus a better performance of the solid-state battery. Also, to compensate for swelling due to traveling charge carriers such as, e.g., Li ions, new types of anode structures such as, e.g., nano wires, are developed that swell into empty spaces rather than in the direction of the traveling charge carriers.

### SUMMARY

In one general aspect, the instant application describes a solid-state battery cell that includes a cathode region, an anode region, a separator interconnecting the cathode region and the anode region, the separator including a solid-state electrolyte, a cathode current collector on a surface of the cathode region, an anode current collector on a surface of the anode region, a first piezoelectric layer on a surface of the cathode current collector opposite the cathode region, and a second piezoelectric layer on a surface of the anode current collector opposite the anode region.

The above general aspect may include one or more of the following features. For example, at least one of the first piezoelectric layer and the second piezoelectric layer is powered by a voltage source separate from the solid-state battery cell. For another example, at least one of the first piezoelectric material layer and the second piezoelectric material layer is powered by the solid-state battery cell.

For another example, the solid-state electrolyte includes a ceramic electrolyte. For a further example, at least one of the first piezoelectric material layer and the second piezoelectric material layer include a ceramic material. For example, the ceramic material is a 3D-printed ceramic material.

In another general aspect, the instant application describes a solid-state battery cell that includes a cathode region, a first anode region, a second anode region on an opposite side of the cathode region from the first anode region, a first separator interconnecting the cathode region and the first anode region, the first separator including a first solid-state electrolyte, a second separator interconnecting the cathode region and the second anode region, the second separator including a second solid-state electrolyte, a first anode current collector on a surface of the first anode region, a second anode current collector on a surface of the second anode region, a first piezoelectric layer on a surface of the first anode current collector, and a second piezoelectric layer on a surface of the second anode current collector.

For another example, at least one of the first piezoelectric layer and the second piezoelectric layer is connected to a voltage source. As another example, at least one of the first solid-state electrolyte and the second solid-state electrolyte includes a ceramic electrolyte. For a further example, at least one of the first anode region and the second anode region includes a lithium anode.

In yet another general aspect, the instant application describes a battery that includes a plurality of solid-state cells arranged in a stack, the stack including a first cell at a first end thereof and a last cell at a second end thereof opposite the first end. Each of the plurality of cells includes a cathode region, an anode region, a separator interconnecting the cathode region and the anode region, the separator including a solid-state electrolyte, a cathode current collector on a surface of the cathode region of the first cell, and an anode current collector on a surface of the anode region of the last cell, a first piezoelectric layer on a surface of the cathode current collector, and a second piezoelectric layer on a surface of the anode current collector.

For another example, at least one of the first piezoelectric material layer and the second piezoelectric material layer is connected to a voltage source located inside the battery. For a further example, at least one of the first piezoelectric material layer and the second piezoelectric material layer is connected to one or more of the plurality of solid-state cells. As another example, the battery is encased in a receptacle, and the voltage source is inside the receptacle.

In yet another general aspect, the instant application describes a battery that includes a plurality of solid-state cells arranged in a stack, the stack including a first cell at a first end thereof and a last cell at a second end thereof opposite the first end. Each of the plurality of cells includes a cathode region, a first anode region, a second anode region on an opposite side of the cathode region from the first anode region, a first separator interconnecting the cathode region and the first anode region, the first separator including a first solid-state electrolyte, a second separator interconnecting the cathode region and the second anode region, the second separator including a second solid-state electrolyte, a first anode current collector on a surface of the first anode region of the first cell, a second current collector on a surface of the second anode region of the last cell, a first piezoelectric layer on a surface of the first anode current collector, and a second piezoelectric layer on a surface of the second anode current collector.

In one general aspect, the instant application describes a method of operating a solid-state battery cell that includes detecting a first voltage at one of the first piezoelectric layer and the second piezoelectric layer, and when the first voltage is a non-zero voltage, applying a second voltage to the one of the first piezoelectric layer and the second piezoelectric layer.

For another example, the at least one of the first piezoelectric material layer and the second piezoelectric material layer generate pressure against an adjacent layer due to the applied second voltage. As another example, the applied second voltage is equal to the detected first voltage.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

### BRIEF DESCRIPTION OF THE DRAWINGS

The drawing figures depict one or more implementations in accord with the present teachings, by way of example only, not by way of limitation. In the figures, like reference numerals refer to the same or similar elements. Furthermore, it should be understood that the drawings are not necessarily to scale.

FIG. 1 is a cross-section view of a solid-state cell battery that includes stacked sub-cells.

FIG. 2 is a cross-section of a solid-state battery with piezoelectric compensation layers, according to various implementations.

FIG. 3 is a cross-section of a solid-state battery with piezoelectric compensation layers during operation of the solid-state battery, according to various implementations.

FIG. 4 is a cross-section of a solid-state battery with piezoelectric compensation layers during operation of the solid-state battery, according to various implementations.

FIG. 5 is a cross-section of a solid-state battery with piezoelectric compensation layers during operation of the solid-state battery, according to various implementations.

FIG. 6 is a cross-section of a solid-state battery with piezoelectric compensation layers during operation of the solid-state battery, according to various implementations.

FIG. 7 is an illustration of a power source for piezoelectric compensation layers in a solid-state battery, according to various implementations.

FIG. 8 is a flowchart illustrating a method of compensating material changes in a solid-state battery, according to various implementations.

### DETAILED DESCRIPTION

In the following detailed description, numerous specific details are set forth by way of examples in order to provide a thorough understanding of the relevant teachings. However, it should be apparent that the present teachings may be practiced without such details. In other instances, well known methods, procedures, components, and/or circuitry have been described at a relatively high-level, without detail, in order to avoid unnecessarily obscuring aspects of the present teachings.

Solid-state batteries present a technical problem where one or both electrodes of a given solid-state battery may undergo material losses during operation of the battery, and the loss of material may impair the quality and performance of the battery. To address these technical problems and more, in various implementations, this description provides a technical solution for solid-state batteries, where a piezoelectric layer is provided on each electrode, and the piezoelectric layer is configured to expand and apply a pressure on an adjacent electrode when electric power is applied to it. The adjacent electrode may undergo, e.g., material changes such as material losses, or other physical degradation during operation of the battery. As a result of the applied pressure, an integrity of the interface between the adjacent electrode and the current collector, or between the adjacent electrode and the solid electrolyte, may be maintained, and the performance of the solid-state battery may be preserved.

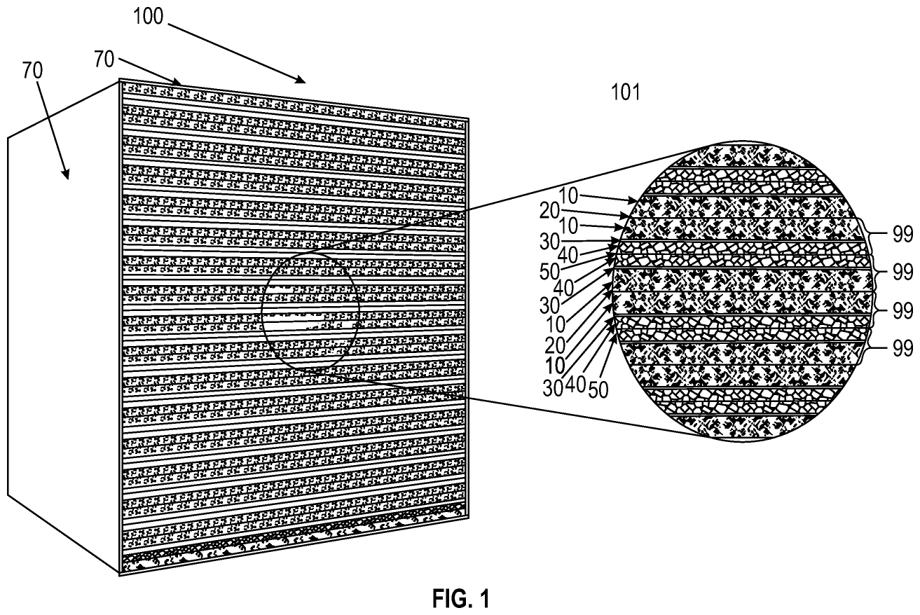

An exemplary advanced solid-state cell is illustrated in FIG. 1. As shown in FIG. 1, the exemplary advanced solid-state cell includes stacked sub-cells 99. Each sub-cell 99 can include alternating thin layers of anode 40 and cathode 10 materials, separated by a separator 30. In some implementations of the disclosure, the separator 30 can include a solid state electrolyte. For example, the separator 30 can be a thin layer of ceramic electrolyte material. The thin layer of ceramic electrolyte material may be 0.01 μm to 1000 μm thick. Thin layers are advantageous because they allow the cells to have low parasitic series resistance, but thicker layers have a lower probability of having apertures that would allow the cell to experience electrical breakdown. It should be understood the materials introduced herein are examples. Moreover, the thickness of the ceramic electrolyte material is provided herein as an example thickness range. The present disclosure can include a thickness measurement that fall outside the exemplary range. The layer 70 surrounding the composite of sub-cells 99 is a ceramic sheath, providing mechanical support and physical protection for the layers within.

In some implementations of the disclosure, each layer of anode materials 40 and cathode materials 10 can mechanically define the anodes and cathodes for two sub-cells 99 of a many layered cell 100. Each of the sub-cells 99 can be separated by a current collector 50. That is, the boundary between the first and second of these sub-cells 99 can be defined by current collector 50. In some implementations, the current collector 50 can include low reactivity metals or metallic compounds, like copper, aluminum, gold, platinum, tin oxide or indium oxide. Other materials can be implemented as a current collector 50 herein.

Alternatively, each sub-cell 99 of the cell 100 can be completely separated from adjacent sub-cells by layers of insulating material. In some implementations, the insulating material can include dielectric material, ceramic materials such as porcelain. Other ceramics can include alumina and zirconia. Other known materials can be implemented as an insulating material herein. Specifically, each sub-cell is a layered structure, made up of two different classes of solid-state electrolyte materials. A layer of low porosity, impenetrable ceramic electrolyte material can function as each cell's separator 30. For example, a separator 30 including a layer of nonporous ceramic electrolyte might successfully be as thin as 10 μm, but a separator including a ceramic electrolyte of 5% porosity might have to be 30 μm thick to avoid penetrating apertures, giving a sub-cell 99 three times more internal series resistance and correspondingly poorer electrical performance. Layers of relatively high but controlled porosity can function specifically as the anode layers 40 and the cathode layers 10. For example, some low porosity ceramic electrolyte material can include lithium aluminum titanium phosphate, lithium aluminum germanium phosphate, lithium lanthanum zirconate garnet (LLZO), LLZO garnet with calcium and niobium substitutions (LLCZN). An anode region 40 or cathode region 10 with 70% porosity would be able to hold twice as much lithium-bearing material as a region having 35% porosity, meaning that for the same total volume, the 70% version would have twice the storage capacity.

In various implementations, during the charging-discharging process of a solid-state battery, the respective thicknesses of the cathode and of the anode increase and decrease as a function of the charging or discharging cycle of the solid-state battery. As a result of these changes in the thicknesses of the cathode and the anode, the battery cell of the solid-state battery may experience swelling because the changes in the thicknesses of the cathode and of the anode are not equivalent in size and do not naturally compensate for each other. The swelling of the solid-state battery that is due to these material changes may be the cause of failure of the solid-state battery.

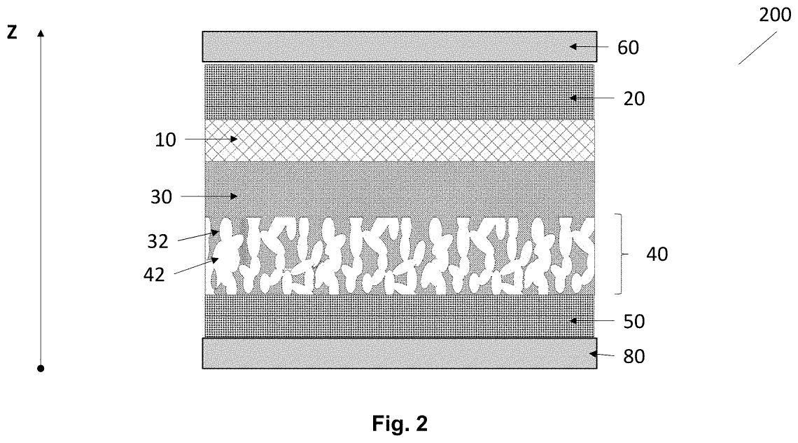

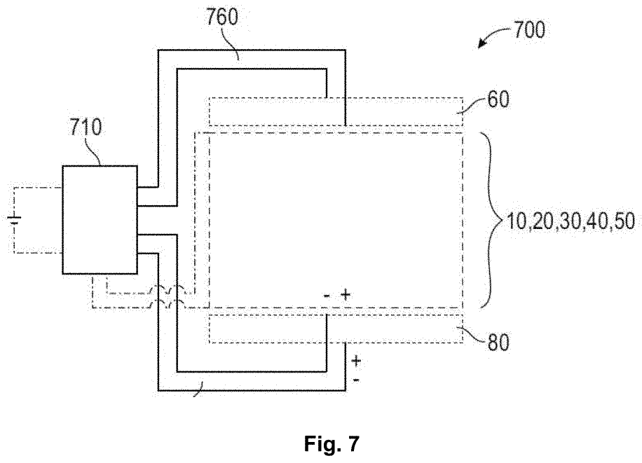

FIG. 2 is a cross-section of a solid-state battery 200 with piezoelectric compensation layers, according to various implementations. The solid-sate battery 200 includes an anode electrode region 40 that includes anode material 42 and may also include pores 32, the anode region 40 being in contact with an anode current collector 50. The solid-state battery 200 also includes a cathode current collector 20 connected to a cathode structure 10, and a ceramic electrolyte separator 30 separating the cathode structure 10 from the anode region 40. The solid-state battery 200 further includes a piezoelectric layer 60 on the cathode current collector 20 and a piezoelectric layer 80 on the anode current collector 50. The piezoelectric layers 60 and 80 may be or include a ceramic piezoelectric material, and may include a non-ceramic material. The piezoelectric layers 60 and 80 may be configured to be powered by a power source, as discussed with respect to FIG. 7 below. Accordingly, during operation of the solid-state battery 200, the piezoelectric layers 60 and 80 may be selectively activated by, e.g., subjecting them to a source of electric power, which results in their increasing thickness in the Z thickness illustrated in FIG. 2. When the electrode, e.g., anode region 40 or cathode structure 10, is pressed against the piezoelectric layer 60/80 in a confined space, e.g., in a receptacle, the increase in the thickness of the piezoelectric layer 60/80 results in an increased pressure applied against the anode region 40 or cathode structure 10. In various implementations, the solid-state battery 200 is encased in a rigid receptacle (not shown). Accordingly, the piezoelectric layers 60 and 80 compensate for losses of material of changes in the shape of the cathode structure 10 and/or the anode region 40.

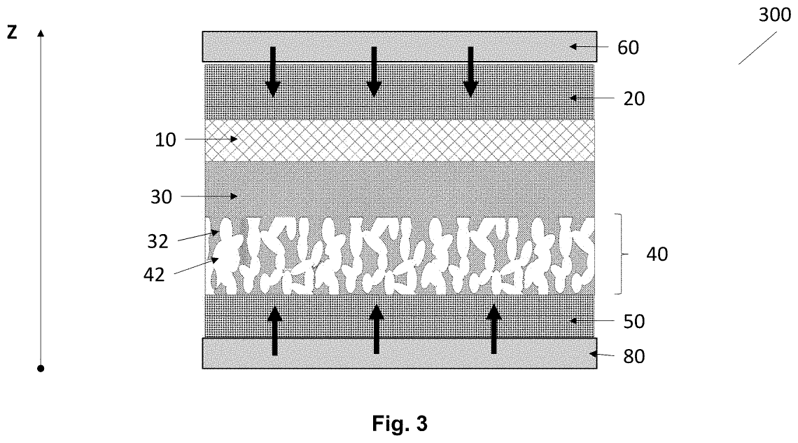

FIG. 3 is a cross-section of a solid-state battery 300 with piezoelectric compensation layers during operation of the solid-state battery, according to various implementations. The solid-state battery 300 shows arrows which are parallel to the Z axis. The arrows illustrate a pressure that may be applied by the piezoelectric layers 60 and 80 to the cathode structure 10 and the anode region 40, respectively. The piezoelectric layers 60 and 80 may apply pressure to the cathode structure 10 and the anode region 40 at the same time or at different times, and may be applied selectively. For example, during operation of the solid-state battery, as material changes may occur either at the cathode structure 10 or the anode region 40, one or both of the piezoelectric layers 60 and 80 may receive a voltage input and translate that voltage input into a mechanical force applied against the cathode structure 10 and/or the anode region 40. For example, the mechanical force may be applied against the cathode structure 10 and the anode region 40 along the Z axis illustrated in FIG. 3. Because of the current collectors 20 and 50 located between the cathode structure 10 and the anode region 40 and the piezoelectric layers 60 and 80, the force generated by the piezoelectric layers 60 and 80 may be applied to the cathode structure 10 and the anode region 40 via the current collectors 20 and 50, respectively. Accordingly, the piezoelectric layers 60 and 80 compensate for losses of material of changes in the shape of the cathode structure 10 and/or the anode region 40.

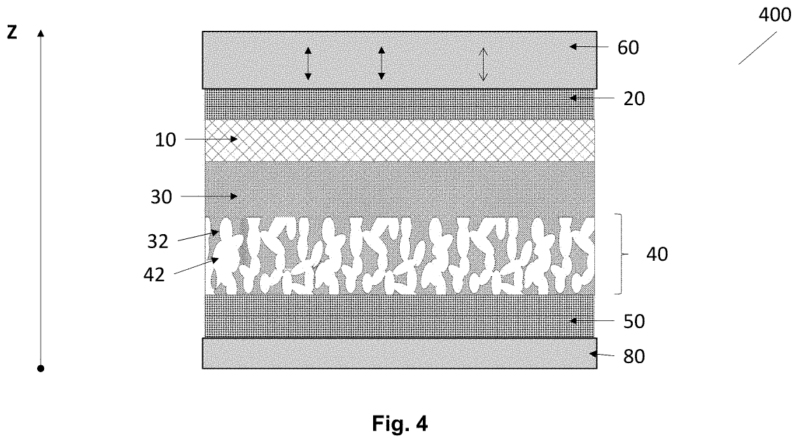

FIG. 4 is a cross-section of a solid-state battery 400 with piezoelectric compensation layers during operation of the solid-state battery, according to various implementations. The solid-state battery 400 include a cathode structure 10. As shown, the cathode structure 10 is shrinking due to loss of material during a charging operation of the solid-state battery 400. These material changes may occur when, e.g., the lithium in the cathode structure 10 dissolves as a result of oxidation, and lithium ions are released during the charging cycle. The lithium ions may then travel across the electrolyte separator 30 over to the anode region 40. Accordingly, the cathode structure 10 may lose some material (e.g., lithium) and may experience a reduction in thickness as a result of the loss of material during the charging cycle of operation of the solid-state battery 400. For example, the reduction in the thickness may be a thickness decrease along the Z axis illustrated in FIG. 4. As another result of the lithium ions dissolving from the cathode structure 10 and traveling over to the anode region 40 to be reduced, the anode region 40 may experience an increase in thickness because of the influx of additional material (e.g., lithium). Accordingly, during the charging cycle of the solid-state battery 400, the cathode structure 10 may experience a decrease in thickness due to loss of material, and the anode region 40 may experience an increase in thickness to addition of material (i.e., lithium). For example, the increase and decrease in the thickness of the cathode structure 10 and the anode region 40 may take place along the Z axis illustrated in FIG. 4.

In various implementations, in order to compensate for the loss of material for the cathode structure during the charging process, the piezoelectric layer 60, under the impetus of an electric voltage source, generates a force or pressure and expands against the cathode current collector 20 and the cathode structure 10. Accordingly, the applied pressure may maintain the quality of the interfaces between several layers of the battery 400: the interface between, e.g., the cathode current collector 20 and the cathode structure 10, the interface between the cathode structure 10 and the solid electrode separator 30, and possibly the interface between the solid electrolyte separator 30 and the anode region 40. As a result of the application of pressure from the piezoelectric layer 60 against the current collector 20, any deleterious effects caused by material losses of the cathode structure 10 on the interface between the layers of the battery 400 may be mitigated, reduced or compensated. Accordingly, the quality of the interface between the layers of the battery 400, e.g., between the cathode structure 10 and the ceramic electrolyte separator 30, may be maintained to ensure a good operation state of the solid-state battery cell 400.

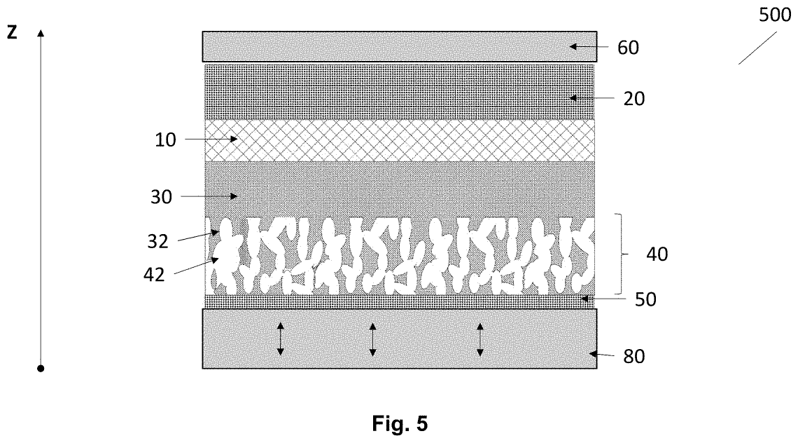

FIG. 5 is a cross-section of a solid-state battery 500 with piezoelectric compensation layers during operation of the solid-state battery, according to various implementations. The solid-state battery 500 include an anode region 40. As shown, the anode region 40 is shrinking due to loss of material during a discharging operation of the solid-state battery 500. During a discharging process of the solid-state battery 500, material losses in the anode region 40 may occur. These material losses may occur when, e.g., the lithium in the anode region 40 which flowed to the anode region 40 as during the charging process may now undergo an oxidation at the during the discharging process and travel back across the electrolyte separator 30 to the cathode structure 10 to be reduced to elemental lithium at the cathode structure 10. Accordingly, the anode region 40 may lose some material (e.g., lithium) and may see a reduction in thickness as a result of the loss of material during the discharge cycle of the solid-state battery 500. As another result of the discharge process, when the lithium ions travel over to the cathode structure 10, the cathode structure 10 may see an increase in thickness because of the influx of lithium ions. Specifically, during the discharging cycle of the solid-state battery 500, there is an increase in the thickness of the cathode structure 10 and a decrease in the thickness of the anode region 40.

As a result of this change in thickness in the anode region 40, the piezoelectric layer 80, under the impetus of a voltage source, generates a force or pressure and expands against the anode region 40. Accordingly, the applied pressure from the piezoelectric layer 80 may maintain the quality of the interfaces between several layers of the battery 500: the interface between, e.g., the anode current collector 50 and the anode region 40, the interface between the anode region 40 and the solid electrode separator 30, and possibly the interface between the solid electrode separator 30 and the cathode structure 10. As a result of the application of pressure against the current collector 50 by the piezoelectric layer 80, any deleterious effects due to material losses of the anode region 40 on the interface between the layers of the battery 500 may be mitigated, reduced or compensated. Accordingly, the quality of the interface between the layers of the battery 500, e.g., between the anode region 40 and the ceramic electrolyte separator 30, may be maintained to ensure a good operation state of the solid-state battery cell 500.

In various implementations, the piezoelectric layers 80 or 60 may also be used as sensors to sense the extent of the material changes occurring at the cathode structure 10 or at the anode region 40. For example, the pressure applied by either one of the cathode structure 10 or the anode region 40 can be measured via a voltage detected by the piezoelectric layer 80 or 60. Such measurement may be indicative of the material changes occurring at the cathode structure 10 or at the anode region 40. For example, a voltage reading of the piezoelectric layer 80 or 60 may be indicative of a given amount of material change expressed in added pressure or decreased pressure against the piezoelectric layer 80 or 60.

In various implementations, the voltage measured by the piezoelectric layer 80 or 60 may be used to apply the correct amount of pressure to cathode structure 10 or the anode region 40. For example, when a voltage is measured at the piezoelectric layer 80 or 60 as a result of added or reduced pressure from the cathode structure 10 or the anode region 40, substantially the same voltage may be used to apply to the piezoelectric layer 80 or 60 to in turn apply a compensating pressure on the cathode structure 10 or the anode region 40.

Although FIG. 5 illustrates a single battery cell including a cathode current collector, a cathode, an electrolyte, an anode and an anode current collector, various implementations include a stack of battery cells where the entire stack of cells may have one piezoelectric layer on each side. Accordingly, the piezoelectric layers on each side of the entire stack of battery cells may detect material changes in any one of the layers within that stack, and can apply a pressure against the entire stack of layers, and thus may compensate for losses of material of changes in the shape of the cathode structure 10 and/or the anode region 40.

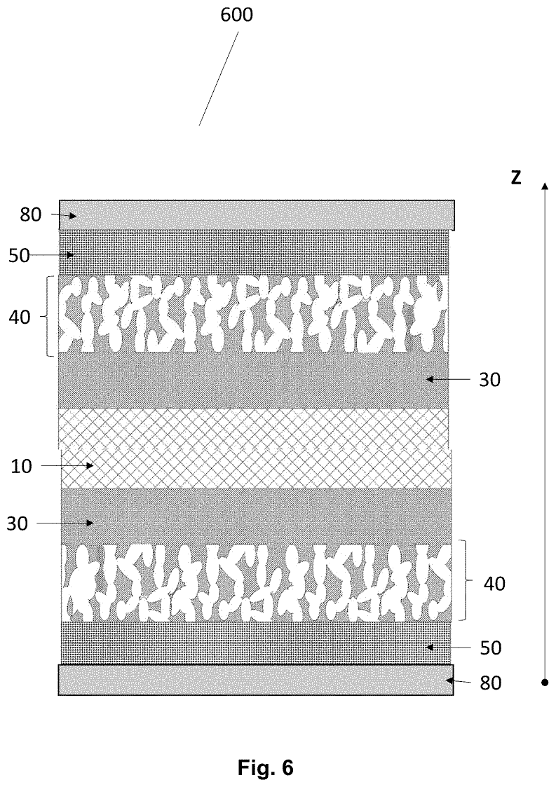

FIG. 6 is a cross-section of a solid-state battery with piezoelectric compensation layers, according to various implementations. In FIG. 6, instead of having the piezoelectric layers 60 and 80 on either side of the solid-state battery cell 600, the cell is configured such that two consecutive cells share a same cathode structure 10. Accordingly, both sides of the cell 600 have an anode region 40, with an anode current collector 50 on each anode region 40, and a piezoelectric layer 80 on each of the anode current collectors 50. In this configuration, the cathode structure 10 is at the center of the cross-section of the solid-state battery cell 600. As such, the piezoelectric layers 80 operate as discussed above and compensate for any material or volume changes in the anode regions 40 by applying a mechanical force that is perpendicular to a longitudinal direction of the anode regions 40. Both piezoelectric layers 80 may not necessarily apply the mechanical force at the same time, and may be selectively activated by being subjected to electric power coming from a voltage source.

FIG. 7 is an illustration of a power source for piezoelectric compensation layers in a solid-state battery, according to various implementations. In FIG. 7, a solid-state battery 700 includes a stack of layers 10-50 corresponding to, as discussed above with respect to FIGS. 2-6, a cathode structure 10, a cathode current collector 20, a ceramic electrolyte separator 30, an anode region 40, and an anode current collector 50. In FIG. 7, a piezoelectric layer 60 is on the cathode current collector 20, and a piezoelectric layer 80 is on the anode current collector 50, similarly to the battery cell structures discussed with respect to FIGS. 1-6. In FIG. 7, the piezoelectric layer 60 is connected to a voltage source 710 via electrical connections 760, and the piezoelectric layer 80 is connected to the voltage source 710 via electrical connections 780. Accordingly, when either one of the piezoelectric layer 60 and the piezoelectric layer 80 receives a voltage form the voltage source 710, the piezoelectric layer 60 or 80 responds by expanding and generating a mechanical force against the cathode structure 10 or the anode region 40. Although FIG. 7 shows that both piezoelectric layers 60 and 80 are connected to the same voltage source 710, they may each have their own separate voltage source.

In various implementations, the voltage source 710 is connected to the solid-state battery 700 and is powered by the solid-state battery 700. In other implementations (not shown), the voltage source 710 is independent from the solid-state battery 700 and is not electrically connected to the solid-state battery 700.

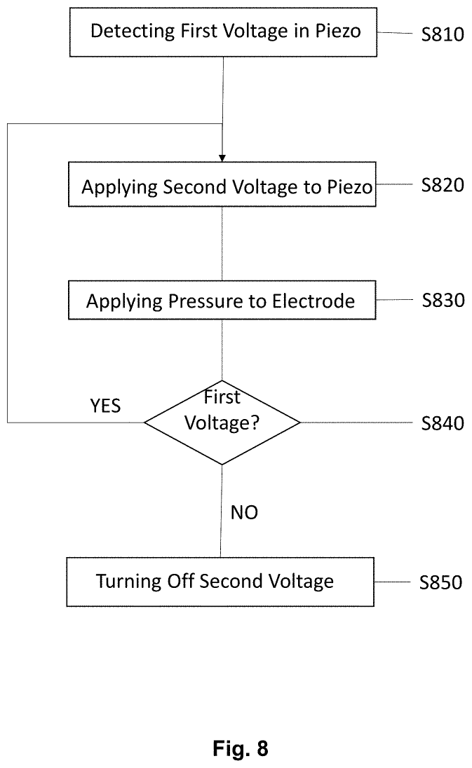

FIG. 8 is a flowchart illustrating a method of compensating material changes in a solid-state battery, according to various implementations. With reference to FIG. 2 above, during operation of the solid-state battery 200, material changes take place at the cathode structure 10 and/or at the anode region 40. For example, material changes may be a decrease in thickness of the cathode structure 10, indicative of a loss of material due to dissolution of lithium during the charging cycle of the solid-state battery. In FIG. 8, a change in at least one of the volume, the weight, the density, or the like, of the material of an electrode (e.g., cathode structure 10 or anode region 40) is detected. For example, at S810 and during operation of the battery, the detection of material change is performed via the detection of a first voltage emitted by the piezoelectric layer 60 under pressure from the cathode structure 10, or emitted by the piezoelectric layer 80 under pressure from the anode region 40. The detected first voltage may be correlated to the amount of pressure applied to the piezoelectric layer 60 or 80 by the underlying cathode structure 10 or anode region 40.

In various implementations, at S820, as a result of detecting the first voltage, a second voltage is applied to the piezoelectric layer that is on the side of the electrode for which the first voltage has been detected. For example, when the first voltage is detected from the piezoelectric layer 60, the second voltage may be applied to the piezoelectric layer 60 to urge the piezoelectric layer 60 to apply pressure against the cathode structure 10. For example, when the first voltage is detected from the piezoelectric layer 80, the second voltage may be applied to the piezoelectric layer 80 to urge the piezoelectric layer 80 to apply pressure against the anode region 40. For example, the second voltage may be substantially the same as the first voltage.

In various implementations, at S830, as a result of receiving the second voltage, the piezoelectric layer 60 or 80 generates a mechanical force against the cathode structure 10 or the anode region 40. More specifically, when a current collector is between the piezoelectric layer and the electrode, the piezoelectric layer generates a force against the current collector at S830, and the current collector transmits that force to the cathode structure 10 or the anode region 40. As a result of the application of the mechanical force by the piezoelectric layer, the quality of the interface between various layers of the battery may be maintained or improved. For example, the quality of the interface between the cathode structure 10/anode region 40 and the current collector 20/50, the interface between the cathode structure 10/anode region 40 and the solid-state electrolyte, or even the interface between the solid-state electrolyte and the cathode structure 10/anode region 40 on the opposite side of the battery. For example, improving or maintain the interface between the layers of the battery includes improving or maintaining the surface of the contact area between those layers. Accordingly, if an electrode (i.e., cathode structure 10/anode region 40) undergoes material losses, then by being pressed against the solid-state electrolyte, the electrode can maintain an appropriate level of contact surface area at the interface with the solid-state electrolyte.

In various implementations, at S840, the method determines whether a voltage such as the first voltage discussed above is still detected at either the piezoelectric layer 60 or 80. If at S840, a voltage is detected at either of the piezoelectric layers 60 or 80, then the method continues to S820 to apply a second voltage, as discussed above. If at S840 a voltage is not detected at either of the piezoelectric layers 60 or 80, then the method goes to S850 and the second voltage is no longer applied to either of the piezoelectric layers 60 or 80.

In the following, further features, characteristics and advantages of the instant application will be described by means of items:

Item 1: A solid-state battery cell includes a cathode region, an anode region, a separator interconnecting the cathode region and the anode region, the separator including a solid-state electrolyte, a cathode current collector on a surface of the cathode region, an anode current collector on a surface of the anode region, a first piezoelectric layer on a surface of the cathode current collector opposite the cathode region, and a second piezoelectric layer on a surface of the anode current collector opposite the anode region.

Item 2: The solid-state battery cell of item 1, wherein at least one of the first piezoelectric layer and the second piezoelectric layer is powered by a voltage source separate from the solid-state battery cell.

Item 3: The solid-state battery cell of item 1 or 2, wherein at least one of the first piezoelectric material layer and the second piezoelectric material layer is powered by the solid-state battery cell.

Item 4: The solid-state battery cell of any of items 1-3, wherein the solid-state electrolyte includes a ceramic electrolyte.

Item 5: The solid-state battery cell of any of items 1-4, wherein at least one of the first piezoelectric material layer and the second piezoelectric material layer include a ceramic material. For example, the ceramic material is a 3D-printed ceramic material.

Item 6: A solid-state battery cell includes a cathode region, a first anode region, a second anode region on an opposite side of the cathode region from the first anode region, a first separator interconnecting the cathode region and the first anode region, the first separator including a first solid-state electrolyte, a second separator interconnecting the cathode region and the second anode region, the second separator including a second solid-state electrolyte, a first anode current collector on a surface of the first anode region, a second anode current collector on a surface of the second anode region, a first piezoelectric layer on a surface of the first anode current collector, and a second piezoelectric layer on a surface of the second anode current collector.

Item 7: The solid-state battery cell of item 6, wherein at least one of the first piezoelectric layer and the second piezoelectric layer is connected to a voltage source.

Item 8: The solid-state battery cell of item 6 or 7, wherein at least one of the first solid-state electrolyte and the second solid-state electrolyte includes a ceramic electrolyte.

Item 9: The solid-state battery cell of any of items 6-8, wherein at least one of the first anode region and the second anode region includes a lithium anode.

Item 10: A battery includes a plurality of solid-state cells arranged in a stack, the stack including a first cell at a first end thereof and a last cell at a second end thereof opposite the first end. Each of the plurality of cells includes a cathode region, an anode region, a separator interconnecting the cathode region and the anode region, the separator including a solid-state electrolyte, a cathode current collector on a surface of the cathode region of the first cell, and an anode current collector on a surface of the anode region of the last cell, a first piezoelectric layer on a surface of the cathode current collector, and a second piezoelectric layer on a surface of the anode current collector.

Item 11: The battery of item 10, wherein at least one of the first piezoelectric material layer and the second piezoelectric material layer is connected to a voltage source located inside the battery.

Item 12: The battery of item 10 or 11, wherein at least one of the first piezoelectric material layer and the second piezoelectric material layer is connected to one or more of the plurality of solid-state cells.

Item 13: The battery of any of items 10-12, wherein the battery is encased in a receptacle, and the voltage source is inside the receptacle.

Item 14: A battery includes a plurality of solid-state cells arranged in a stack, the stack including a first cell at a first end thereof and a last cell at a second end thereof opposite the first end. Each of the plurality of cells includes a cathode region, a first anode region, a second anode region on an opposite side of the cathode region from the first anode region, a first separator interconnecting the cathode region and the first anode region, the first separator including a first solid-state electrolyte, a second separator interconnecting the cathode region and the second anode region, the second separator including a second solid-state electrolyte, a first anode current collector on a surface of the first anode region of the first cell, a second current collector on a surface of the second anode region of the last cell, a first piezoelectric layer on a surface of the first anode current collector, and a second piezoelectric layer on a surface of the second anode current collector.

Item 15: A method of operating a solid-state battery cell includes detecting a first voltage at one of the first piezoelectric layer and the second piezoelectric layer, and when the first voltage is a non-zero voltage, applying a second voltage to the one of the first piezoelectric layer and the second piezoelectric layer.

Item 16: The method of item 15, wherein the at least one of the first piezoelectric material layer and the second piezoelectric material layer generate pressure against an adjacent layer due to the applied second voltage.

Item 17: The method of item 15 or 16, wherein the applied second voltage is equal to the detected first voltage.

Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that includes a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that includes the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it may be seen that various features are grouped together in various examples for the purpose of streamlining the disclosure. This method of disclosure is not to be interpreted as reflecting an intention that the claims require more features than are expressly recited in each claim. Rather, as the following claims reflect, inventive subject matter lies in less than all features of a single disclosed example. Thus, the following claims are hereby incorporated into the Detailed Description, with each claim standing on its own as a separately claimed subject matter.

What is claimed is:

1. A solid-state battery cell comprising:
a cathode region;
an anode region;
a separator interconnecting the cathode region and the anode region, the separator including a solid-state electrolyte;
a cathode current collector on a surface of the cathode region;
an anode current collector on a surface of the anode region;
a first piezoelectric layer on a surface of the cathode current collector opposite the cathode region; and
a second piezoelectric layer on a surface of the anode current collector opposite the anode region.

2. The solid-state battery cell of claim 1, wherein at least one of the first piezoelectric layer and the second piezoelectric layer is powered by a voltage source separate from the solid-state battery cell.

3. The solid-state battery cell of claim 1, wherein at least one of the first piezoelectric layer and the second piezoelectric layer is powered by the solid-state battery cell.

4. The solid-state battery cell of claim 1, wherein the solid-state electrolyte comprises a ceramic electrolyte.

5. The solid-state battery cell of claim 1, wherein at least one of the first piezoelectric layer and the second piezoelectric layer comprise a ceramic material.

6. The solid-state battery cell of claim 5, wherein the ceramic material is a 3D-printed ceramic material.

7. The solid-state battery cell of claim 1, wherein the anode region comprises a lithium anode.

8. A solid-state battery cell comprising:
a cathode region;
a first anode region;
a second anode region on an opposite side of the cathode region from the first anode region;
a first separator interconnecting the cathode region and the first anode region, the first separator including a first solid-state electrolyte;
a second separator interconnecting the cathode region and the second anode region, the second separator including a second solid-state electrolyte;
a first anode current collector on a surface of the first anode region;
a second anode current collector on a surface of the second anode region;
a first piezoelectric layer on a surface of the first anode current collector; and
a second piezoelectric layer on a surface of the second anode current collector.

9. The solid-state battery cell of claim 8, wherein at least one of the first piezoelectric layer and the second piezoelectric layer is connected to a voltage source.

10. The solid-state battery cell of claim 8, wherein at least one of the first solid-state electrolyte and the second solid-state electrolyte comprises a ceramic electrolyte.

11. The solid-state battery cell of claim 8, wherein at least one of the first anode region and the second anode region comprises a lithium anode.

12. A battery comprising:
a plurality of solid-state cells arranged in a stack, the stack including a first cell at a first end thereof and a last cell at a second end thereof opposite the first end, each of the plurality of cells comprising:
a cathode region;
an anode region;
a separator interconnecting the cathode region and the anode region, the separator including a solid-state electrolyte;
a cathode current collector on a surface of the cathode region of the first cell;
an anode current collector on a surface of the anode region of the last cell;
a first piezoelectric layer on a surface of the cathode current collector; and
a second piezoelectric layer on a surface of the anode current collector.

13. The battery of claim 12, wherein at least one of the first piezoelectric layer and the second piezoelectric layer is connected to a voltage source located inside the battery.

14. The battery of claim 12, wherein at least one of the first piezoelectric layer and the second piezoelectric layer is connected to one or more of the plurality of solid-state cells.

15. The battery of claim 14, wherein:
the battery is encased in a receptacle; and
a voltage source is inside the receptacle.

16. A battery comprising:
a plurality of solid-state cells arranged in a stack, the stack including a first cell at a first end thereof and a last cell at a second end thereof opposite the first end, each of the plurality of cells comprising:
a cathode region;
a first anode region;
a second anode region on an opposite side of the cathode region from the first anode region;
a first separator interconnecting the cathode region and the first anode region, the first separator including a first solid-state electrolyte;
a second separator interconnecting the cathode region and the second anode region, the second separator including a second solid-state electrolyte;
a first anode current collector on a surface of the first anode region of the first cell;
a second current collector on a surface of the second anode region of the last cell;
a first piezoelectric layer on a surface of the first anode current collector; and
a second piezoelectric layer on a surface of the second anode current collector.

17. A method of operating the solid-state battery cell of claim 1, the method comprising:
detecting a first voltage at one of the first piezoelectric layer and the second piezoelectric layer; and
when the first voltage is a non-zero voltage, applying a second voltage to the one of the first piezoelectric layer and the second piezoelectric layer.

18. The method of claim 17, further comprising having the at least one of the first piezoelectric layer and the second piezoelectric layer generate pressure against an adjacent layer due to the applied second voltage.

19. The method of claim 17, wherein the applied second voltage is equal to the detected first voltage.
